(19) United States
(12) Patent Application Publication
(10) Pub. No.: US 2018/0166373 A1
(43) Pub. Date: Jun. 14, 2018

(54) METHOD OF MAKING WIRING BOARD WITH INTERPOSER AND ELECTRONIC COMPONENT INCORPORATED WITH BASE BOARD

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 15/881,119

(22) Filed: Jan. 26, 2018

Related U.S. Application Data
(63) Continuation-in-part of application No. 15/605,920, filed on May 25, 2017.
Application No. 15/605,920 is a continuation-in-part of application No. 14/621,332, filed on Feb. 12, 2015.
Application No. 14/621,332 is a continuation-in-part of application No. 14/846,987, filed on Sep. 7, 2015.
Application No. 15/605,920 is a continuation-in-part of application No. 14/621,332, filed on Feb. 12, 2015.
Application No. 14/621,332 is a continuation-in-part of application No. 14/846,987, filed on Sep. 7, 2015.
Application No. 14/846,987 is a continuation-in-part of application No. 14/621,332, filed on Feb. 12, 2015.
(60) Provisional application No. 61/949,652, filed on Mar. 7, 2014.

(51) Int. Cl. H01L 23/498; H01L 21/48; H01L 23/13; H01L 23/31

(52) U.S. Cl. CPC H01L 23/49833; H01L 21/4853; H01L 23/13; H01L 24/48; H01L 23/49827; H01L 23/3121; H01L 21/486; H01L 23/49838

(57) ABSTRACT

A wiring board includes an interposer and an electronic component laterally surrounded by a base board and a dielectric layer and connected to a routing circuitry. The interposer and the electronic component are inserted into a first through opening and a second through opening of the base board, respectively. The dielectric layer covers the top side of the base board and the top surface of the electronic component, and fills in gaps between the interposer and the base board and between the electronic component and the base board. The routing circuitry is deposited on the dielectric layer and electrically connected to the electronic component and a top wiring layer of the base board.

### CROSS REFERENCE TO RELATED APPLICATIONS

This application is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 14/846,987 is a continuation-in-part of U.S. application Ser. No. 14/621,332 filed Feb. 12, 2015. The U.S. application Ser. No. 14/621,332 claims the benefit of filing date of U.S. Provisional Application Ser. No. 61/949,652 filed Mar. 7, 2014. The entirety of each of said Applications is incorporated herein by reference.

### FIELD OF THE INVENTION

The present invention relates to a method of making a wiring board and, more particularly, to a method of making a wiring board having an interposer, an electronic component and a base board incorporated therein.

### DESCRIPTION OF RELATED ART

High-speed semiconductor assemblies such as multi-chip modules often require high performance wiring boards for signal interconnection. However, as the power increases, large amount of heat generated by semiconductor chip would degrade device performance and impose thermal stress on the chip. Ceramic material, such as alumina or aluminum nitride which is thermally conductive, electrically insulative and low in CTE (Coefficient of Thermal Expansion), is often considered as a suitable material for such kind of applications. U.S. Pat. Nos. 8,895,998 and 7,670,872 disclose various wiring boards using ceramic as chip attachment pad material for better reliability. However, as there is no electronic component such as resistor decoupling capacitor or resistor incorporated therein, the electrical performance of these wiring boards is limited.

### SUMMARY OF THE INVENTION

A primary objective of the present invention is to provide a method of making a wiring board having an electronic component and an interposer incorporated in a base board. The method includes depositing a dielectric layer on the base board and leveling the surface of the dielectric layer to that of the interposer so that the thickness difference between the interposer and the base board can be compensated. The dielectric material would also cover the electronic component and fill in the spaces between the base board and the interposer and between the base board and the electronic component, and therefore can mechanically bond the interposer, the electronic component and the base board together.

Another objective of the present invention is to provide a method of making the wiring board having electronic component electrically connected to the base board. The method includes depositing a routing circuitry that laterally extends on the dielectric layer and extends through the dielectric layer to form metallized vias in contact with the base board and is also electrically connected to the electronic component. The routing circuitry may further laterally extend to a top surface of the interposer and provides electrical connection between the electronic component and a built-in circuitry in the interposer.

In accordance with the foregoing and other objectives, the present invention provides a method of making a wiring board, comprising steps of: providing a base board having a top side, a bottom side, a first through opening, a second through opening and a top wiring layer at the top side thereof, wherein each of the first through opening and the second through opening has interior sidewalls extending from the top side and the bottom side; inserting an interposer into the first through opening of the base board, and inserting an electronic component into the second through opening of the base board, wherein the interposer includes a ceramic slug; forming a dielectric layer on a top surface of the electronic component and the top side of the base board and into gaps between peripheral edges of the interposer and the interior sidewalls of the first through opening and between peripheral edges of the electronic component and the interior sidewalls of the second through opening; and forming a routing circuitry on a top surface of the dielectric layer and electrically connected to the electronic component and to the base board through metallized vias.

Unless specifically indicated or using the term “then” between steps, or steps necessarily occurring in a certain order, the sequence of the above-mentioned steps is not limited to that set forth above and may be changed or reordered according to desired design.

Accordingly, the present invention provides a wiring board, comprising: a base board that includes a top side, a bottom side, a first through opening, a second through opening and a top wiring layer at the top side thereof, wherein each of the first through opening and the second through opening has interior sidewalls extending from the top side and the bottom side; an interposer disposed in the first through opening of the base board, wherein the interposer includes a ceramic slug; an electronic component disposed in the second through opening of the base board; a dielectric layer that covers a top surface of the electronic component and the top side of the base board and extends into gaps between peripheral edges of the interposer and the interior sidewalls of the first through opening and between peripheral edges of the electronic component and the interior sidewalls of the second through opening; and a routing circuitry disposed on a top surface of the dielectric layer and electrically connected to the electronic component and to the base board through metallized vias. Further, the present invention also provides a semiconductor assembly that includes a semiconductor device mounted over the top surface of the interposer of the aforementioned wiring board and electrically connected to the routing circuitry.

The wiring board, the semiconductor assembly and the method of making the same according to the present invention have numerous advantages. For instance, incorporating the interposer and the electronic component with the base board is particularly advantageous as the interposer offers CTE-compensated platform for chip attachment, the electronic component improves the electrical characteristics of the assembly, and the base board increases routing flexibility of the wiring board. Depositing the dielectric layer can provide mechanical bonds between the base board and the interposer and between the base board and the electronic component and offer a platform for high resolution circuitries disposed thereon, thereby allowing fine pitch assemblies such as flip chip and surface mount component to be assembled on the wiring board and interconnected to the electronic component by the routing circuitry.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, of a base board in accordance with the first embodiment of the present invention;

FIGS. 3 and 4 are cross-sectional and top perspective views, respectively, of the structure of FIGS. 1 and 2 further provided with an interposer and an electronic component in accordance with the first embodiment of the present invention;

FIGS. 5 and 6 are cross-sectional and top perspective views, respectively, of the structure of FIGS. 3 and 4 further provided with a dielectric layer in accordance with the first embodiment of the present invention;

FIGS. 7 and 8 are cross-sectional and top perspective views, respectively, of the structure of FIGS. 5 and 6 after removal of the upper portion of the dielectric layer in accordance with the first embodiment of the present invention;

FIGS. 9 and 10 are cross-sectional and top perspective views, respectively, of the structure of FIGS. 7 and 8 further provided with first via openings and second via openings in accordance with the first embodiment of the present invention;

FIGS. 11 and 12 are cross-sectional and top perspective views, respectively, of the structure of FIGS. 9 and 10 further provided with a routing circuitry and a plated layer to finish the fabrication of a wiring board in accordance with the first embodiment of the present invention;

FIGS. 13 and 14 are cross-sectional and top perspective views, respectively, of the structure of FIGS. 11 and 12 further provided with a semiconductor device and passive components in accordance with the first embodiment of the present invention;

FIG. 15 is a cross-sectional view of another aspect of the wiring board in accordance with the first embodiment of the present invention;

FIG. 16 is a cross-sectional view of yet another aspect of the wiring board in accordance with the first embodiment of the present invention;

FIG. 17 is a cross-sectional view of yet another aspect of the wiring board in accordance with the first embodiment of the present invention;

FIG. 18 is a cross-sectional view of the structure having a base board, an interposer and an electronic component in accordance with the second embodiment of the present invention;

FIG. 19 is a cross-sectional view of structure of FIG. 18 further provided with a dielectric layer in accordance with the second embodiment of the present invention;

FIG. 20 is a cross-sectional view of structure of FIG. 19 further provided with via openings and through holes in accordance with the second embodiment of the present invention;

FIG. 21 is a cross-sectional view of structure of FIG. 20 further provided with a plated layer in accordance with the second embodiment of the present invention;

FIG. 22 is a cross-sectional view of structure of FIG. 21 further formed with a routing circuitry and a bottom wiring layer to finish the fabrication of a wiring board in accordance with the second embodiment of the present invention;

FIG. 23 is a cross-sectional view of another aspect of the wiring board in accordance with the second embodiment of the present invention;

FIG. 24 is a cross-sectional view of yet another aspect of the wiring board in accordance with the second embodiment of the present invention;

FIG. 25 is a cross-sectional view of yet another aspect of the wiring board in accordance with the second embodiment of the present invention;

FIG. 26 is a cross-sectional view of the structure of FIG. 22 further provided with a semiconductor device and passive components in accordance with the second embodiment of the present invention;

FIG. 27 is a cross-sectional view of the structure of FIG. 22 further provided with semiconductor devices, passive components and an encapsulant in accordance with the second embodiment of the present invention;

FIG. 28 is a cross-sectional view of another aspect of the wiring board further provided with a semiconductor device, passive components and an encapsulant in accordance with the second embodiment of the present invention;

FIG. 29 is a cross-sectional view of yet another aspect of the wiring board further provided with a semiconductor device, passive components and an encapsulant in accordance with the second embodiment of the present invention;

FIG. 30 is a cross-sectional view of another wiring board in accordance with the third embodiment of the present invention;

FIG. 31 is a cross-sectional view of the structure of FIG. 30 further provided with a semiconductor device and passive components in accordance with the third embodiment of the present invention; and

FIG. 32 is a cross-sectional view of another aspect of the wiring board in accordance with the third embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

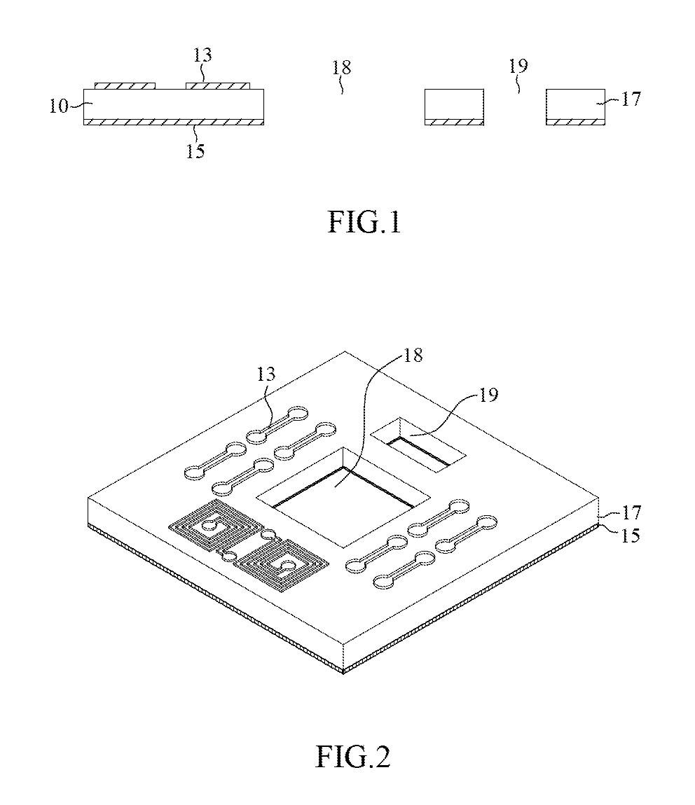

FIGS. 1-12 are schematic views showing a method of making a wiring board that includes a base board, an interposer, an electronic component, a dielectric layer, a routing circuitry and a plated layer in accordance with the first embodiment of the present invention.

FIGS. 1 and 2 are cross-sectional and top perspective views, respectively, of a base board 10. In this embodiment, the base board 10 includes a top wiring layer 13 at its top side, a bottom metal film 15 at its bottom side, a core layer 17 between the top wiring layer 13 and the bottom metal film 15, a first through opening 18, and a second through opening 19. The core layer 17 can be made of ceramic, glass, epoxy resin, molding compound, glass-epoxy, polyimide, or the like. The top wiring layer 13 typically is a patterned copper layer and may be inductors, antenna or any conductive circuitry, whereas the bottom metal film 15 is unpatterned copper layer and completely covers the core layer 17 from below. The first through opening 18 and the second through opening 19 individually have interior sidewalls extending from the top side and the bottom side of the base board 10. The first through opening 18 and the second through opening 19 can be formed by numerous techniques, such as punching, drilling or laser cutting.

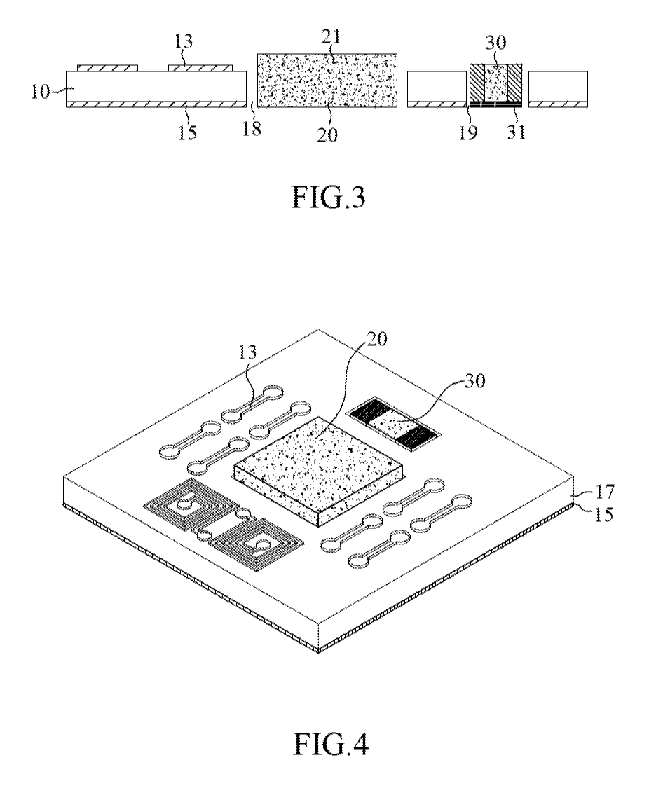

FIGS. 3 and 4 are cross-sectional and top perspective views, respectively, of the structure with an interposer 20 and an electronic component 30 inserted into the first through opening 18 and the second through opening 19 of the base board 10, respectively. Optionally, the bottom surface of the electronic component 30 may include a thermally conductive material 31 at its bottom surface. In this embodiment, the interposer 20 includes a ceramic slug 21 thicker than the base board 10 and has high elastic modulus and low coefficient of thermal expansion (for example, 2×10⁻⁶ K⁻¹ to 10×10⁻⁶ K⁻¹), whereas the electronic component 30 is thinner than the interposer 20 and may be resistors, capacitors, inductors or any other passive or active components. The interposer 20 is placed in the first through opening 18 of the base board 10, with the bottom side of the base board 10 substantially coplanar with the bottom surface of the interposer 20. The electronic component 30 is placed in the second through opening 19 of the base board 10, with the bottom side of the base board 10 substantially coplanar with the bottom surface of the electronic component 30. The first through opening 18 has a dimension larger than the interposer 20, whereas the second through opening 19 has a dimension larger than the electronic component 30. In some cases, the interior sidewalls of the first through opening 18 and the interior sidewalls of the second through opening 19 may be used as alignment guides to ensure the placement accuracy of the interposer 20 and the electronic component 30. Accordingly, the interposer 20 and the electronic component 30 can be accurately confined at predetermined locations, with the peripheral edges of the interposer 20 in close proximity to the interior sidewalls of the first through opening 18 and the peripheral edges of the electronic component 30 in close proximity to the interior sidewalls of the second through opening 19.

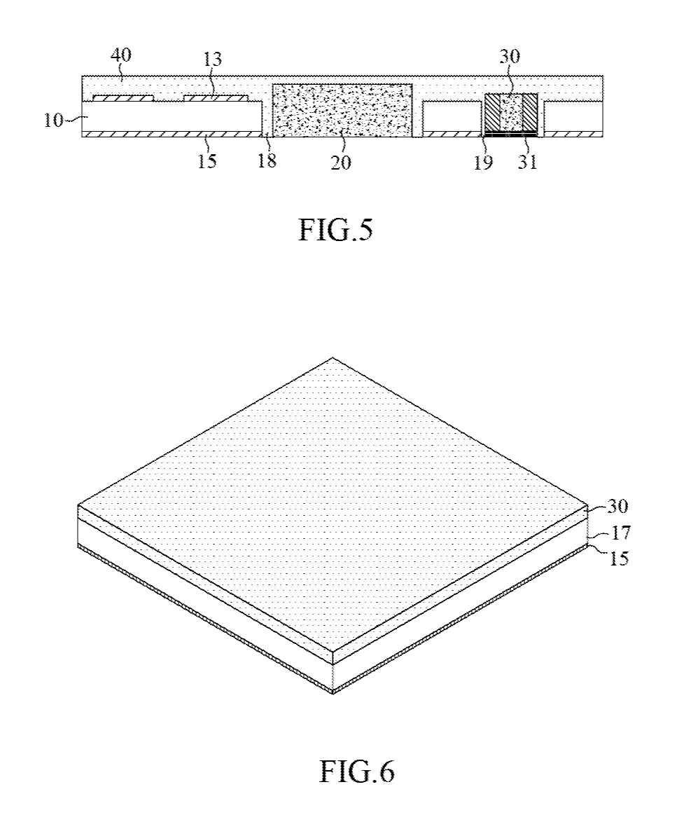

FIGS. 5 and 6 are cross-sectional and top perspective views, respectively, of the structure provided with a dielectric layer 40. The dielectric layer 40 can be deposited by a molding process or other methods such as lamination of epoxy or polyimide. The dielectric layer 40 covers the top side of the base board 10, the top surface of the interposer 20 and the top surface of the electronic component 30, and extends into gaps between peripheral edges of the interposer 10 and the interior sidewalls of the first through opening 18 and between peripheral edges of the electronic component 30 and the interior sidewalls of the second through opening 19. As a result, the dielectric layer 40 laterally covers and surrounds and conformally coats the sidewalls of the interposer 20 and the electronic component 30, and provides mechanical bonds between the base board 10 and the interposer 20 and between the base board 10 and the electronic component 30.

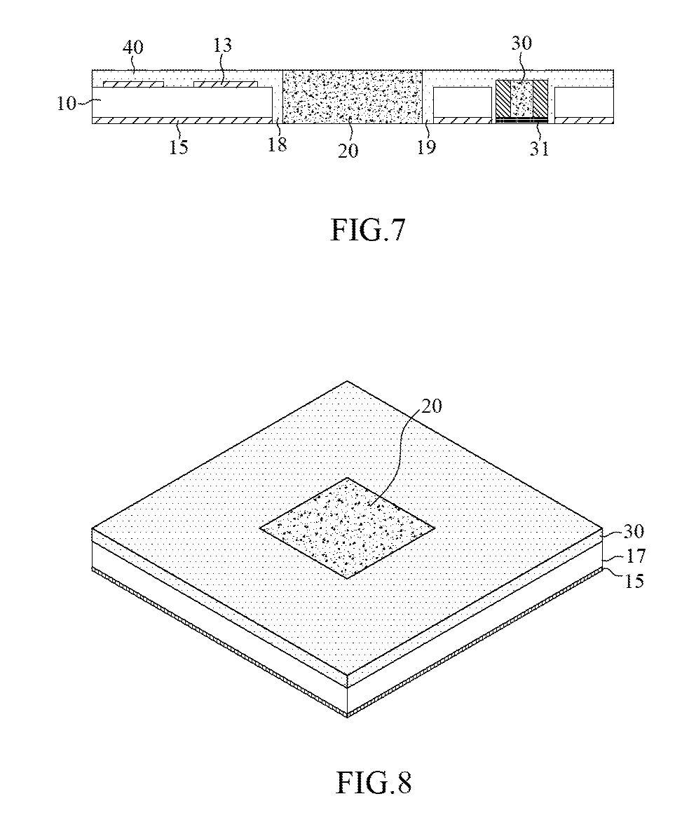

FIGS. 7 and 8 are cross-sectional and top perspective views, respectively, of the structure after removal of the upper portion of the dielectric layer 40. The upper portion of the dielectric layer 40 can be removed by a planarization process to expose the top surface of the interposer 20 from above. The planarization process can be a lapping/grinding process, or a chemical-mechanical polishing (CMP) process. After planarization, the dielectric layer 40 has a top surface substantially coplanar with the top surface of the interposer 20 and a bottom surface substantially coplanar with the bottom side of the base board 10, the bottom surface of the interposer 20 and the bottom surface of the electronic component 30.

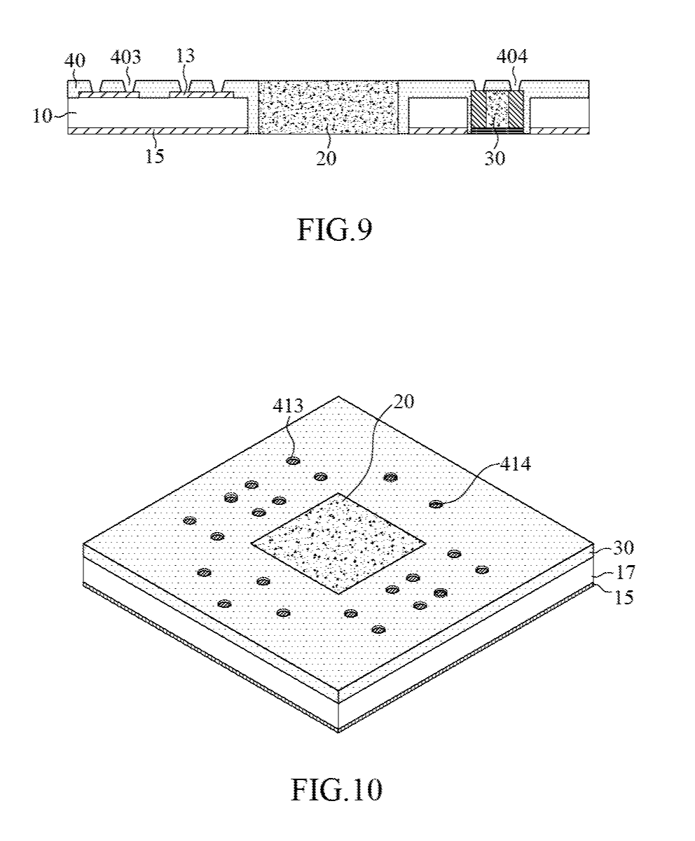

FIGS. 9 and 10 are cross-sectional and top perspective views, respectively, of the structure provided with first via openings 403 and second via openings 404 to expose selected portions of the top wiring layer 13 of the base board 10 and selected portions of the electronic component 30, respectively, from above. The first via openings 403 and the second via openings 404 are formed by numerous techniques including laser drilling, plasma etching and photolithography, and typically have a diameter of 50 microns. Laser drilling can be enhanced by a pulsed laser. Alternatively, a scanning laser beam with a metal mask can be used. The first via openings 403 and the second openings 404 extend through the dielectric layer 40, and are aligned with selected portions of the top wiring layer 13 and selected portions of the electronic component 30, respectively.

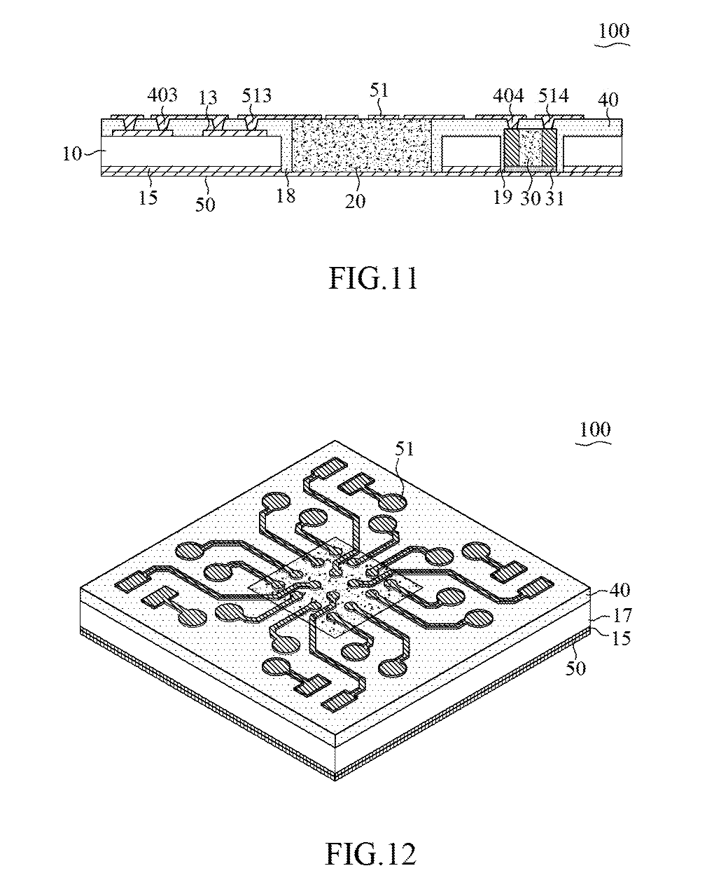

FIGS. 11 and 12 are cross-sectional and top perspective views, respectively, of the structure provided with a routing circuitry 51 by metal pattern deposition described below. The top surface of the structure can be metallized to form an electrically conductive layer (typically a copper layer) as a single layer or multiple layers by numerous techniques, such as electroplating, electroless plating, evaporating, sputtering or their combinations. The electrically conductive layer can be made of Cu, Ni, Ti, Au, Ag, Al, their combinations, or other suitable electrically conductive material. Typically, a seeding layer is formed on the topmost surface of the structure prior to the electrically conductive layer is electroplated to a desirable thickness. The seeding layer may consist of a diffusion barrier layer and a plating bus layer. The diffusion barrier layer is to counterbalance oxidation or corrosion of the electrically conductive layer such as copper. In most cases, the diffusion barrier layer also acts as an adhesion promotion layer to the underlying material and is formed by physical vapor deposition (PVD) such as sputtered Ti or TiW with a thickness in a range from about 0.01 μm to about 0.1 μm. However, the diffusion barrier layer may be made of other materials, such as TaN, or other applicable materials and its thickness range is not limited to the range described above. The plating bus layer is typically made of the same material as the electrically conductive layer with a thickness in a range from about 0.1 μm to about 1 μm. For example, if the electrically conductive layer is copper, the plating bus layer would preferably be a thin film copper formed by physical vapor deposition or electroless plating. However, the plating bus layer may be made of other applicable materials such as silver, gold, chromium, nickel, tungsten, or combinations thereof and its thickness range is not limited to the range described above.

Following the deposition of the seeding layer, a photoresist layer (not shown) is formed over the seeding layer. The photoresist layer may be formed by a wet process, such as a spin-on process, or by a dry process, such as lamination of a dry film. After the photoresist layer is formed, the photoresist layer is patterned to form openings, which are then filled with plated metal such as copper to form the routing circuitry 51. After metal plating, the exposed seeding layer is then removed by etching process to form electrically isolated conductive traces as desired. In this illustration, the routing circuitry 51 is a patterned metal layer, and extends from the top wiring layer 13 and the electronic component 30 in the upward direction, fills up the first via openings 403 and the second via openings 404 to form first metallized vias 513 and second metallized vias 514 in direct contact with the top wiring layer 13 and the electronic component 30, respectively, and extends laterally on the dielectric layer 40. As a result, the routing circuitry 51 provides electrical contacts on the interposer 20 and the dielectric layer 40 and is electrically coupled to the top wiring layer 13 of the base board 10 and the electronic component 30 through the first metallized vias 513 and the second metallized vias 514.

Optionally, the bottom surface of the structure may also be metallized to form a plated layer 50 as a single layer or multiple layers. The plated layer 50 is an unpatterned metal layer (typically a copper layer) that contacts the bottom metal film 15 of the base board 10, the interposer 20 and the thermally conductive material 31 of the electronic component 30 as well as the dielectric layer 40 in the first through opening 18 and the second through opening 19 and completely covers them from below. As a result, the plated layer 50 connects the interposer 20 to the bottom metal layer 13 so as to establish a larger thermal dissipation surface area than interposer 20.

Accordingly, as shown in FIGS. 11 and 12, a wiring board 100 is accomplished and includes a base board 10, an interposer 20, an electronic component 30, a dielectric layer 40, a plated layer 50 and a routing circuitry 51. The interposer 20 is disposed in a first through opening 18 of the base board 10, whereas the electronic component 30 is disposed in a second through opening 19 of the base board 10. The dielectric layer 40 provides mechanical bonds between the interior sidewalls of the base board 10 and the peripheral edges of the interposer 20 and between the interior sidewalls of the base board 10 and the peripheral edges of the electronic component 30. The routing circuitry 51 laterally extends on the top surface of the dielectric layer 40 and the top surface of the interposer 20 to provide horizontal routing, and includes first metallized vias 513 and second metallized vias 514 to provide vertical routing for electrical connection with the top wiring layer 13 of the base board 10 and the electronic component 30. The plated layer 50 is a continuous unpatterned metal layer disposed under the base board 10, the interposer 20 and the electronic component 30, and is thermally conductible to the interposer 20 and the electronic component 30.

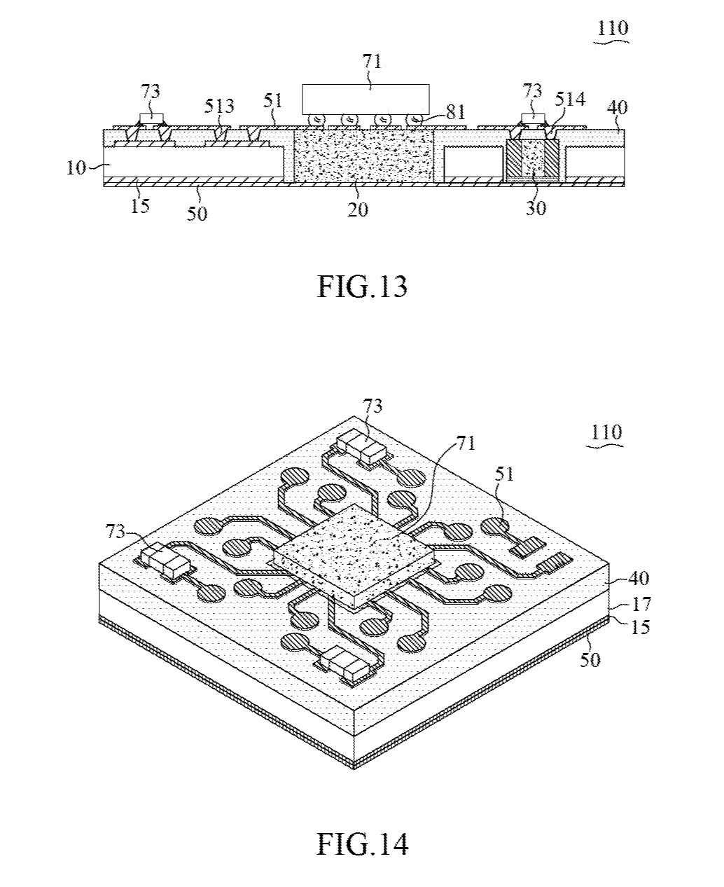

FIGS. 13 and 14 are cross-sectional and top perspective views, respectively, of a semiconductor assembly 110 with a semiconductor device 71 and passive components 73 electrically connected to the wiring board 100 illustrated in FIGS. 11 and 12. The semiconductor device 71, illustrated as a chip, is flip-chip mounted over the top surface of the interposer 20 and electrically coupled to the routing circuitry 51 via conductive bumps 81. The passive components 73 are mounted over the top surface of the dielectric layer 40 and electrically coupled to the routing circuitry 51.

FIG. 15 is a cross-sectional view of another aspect of the wiring board according to the first embodiment of the present invention. The wiring board 120 is similar to that illustrated in FIG. 11, except that it further includes a top build-up circuitry 61 on the routing circuitry 51. In this illustration, the top build-up circuitry 61 includes a resin layer 611 and a conductive trace layer 615. The resin layer 611 covers the routing circuitry 51 from above, and can be made of epoxy resin, glass-epoxy, polyimide, or the like. The conductive trace layer 615 extends laterally on the resin layer 611, and includes third metallized vias 617 in the resin layer 611. The metallized vias 617 contact the routing circuitry 51 and extend through the resin layer 611.

FIG. 16 is a cross-sectional view of yet another aspect of the wiring board according to the first embodiment of the present invention. The wiring board 130 is similar to that illustrated in FIG. 11, except that the interposer 20 further includes a built-in circuitry 25 electrically coupled to the routing circuitry 51.

FIG. 17 is a cross-sectional view of yet another aspect of the wiring board according to the first embodiment of the present invention. The wiring board 140 is similar to that illustrated in FIG. 16, except that it further includes a top build-up circuitry 61 on the routing circuitry 51. As a result, the top build-up circuitry 61 is electrically connected to the top wiring layer 13 of the base board 10, the built-in circuitry 25 of the interposer 20 and the electronic component 30 through the routing circuitry 51.

### Embodiment 2

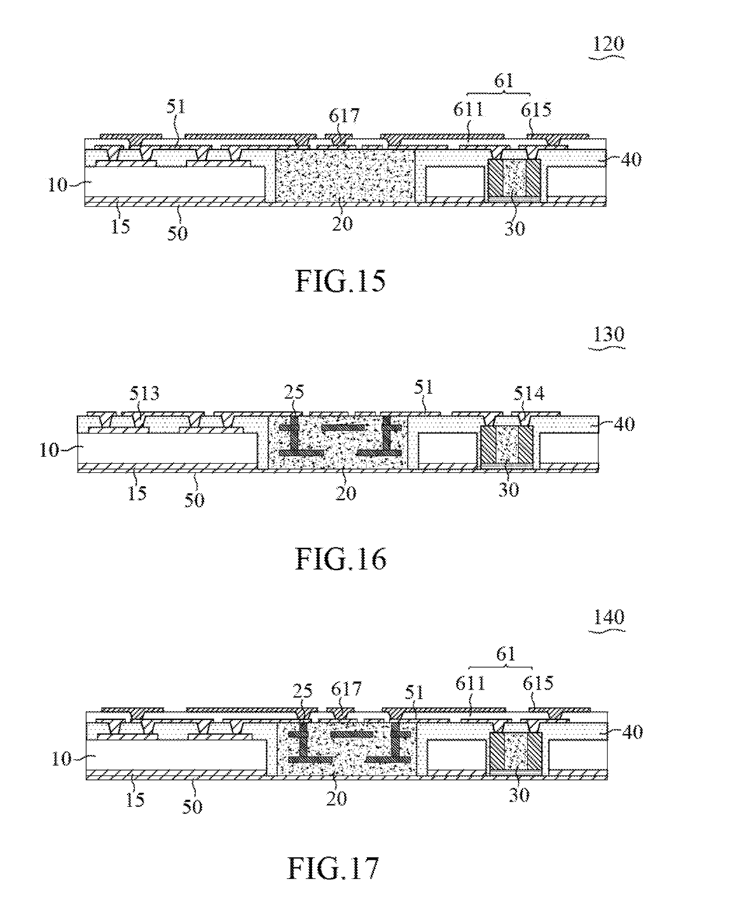

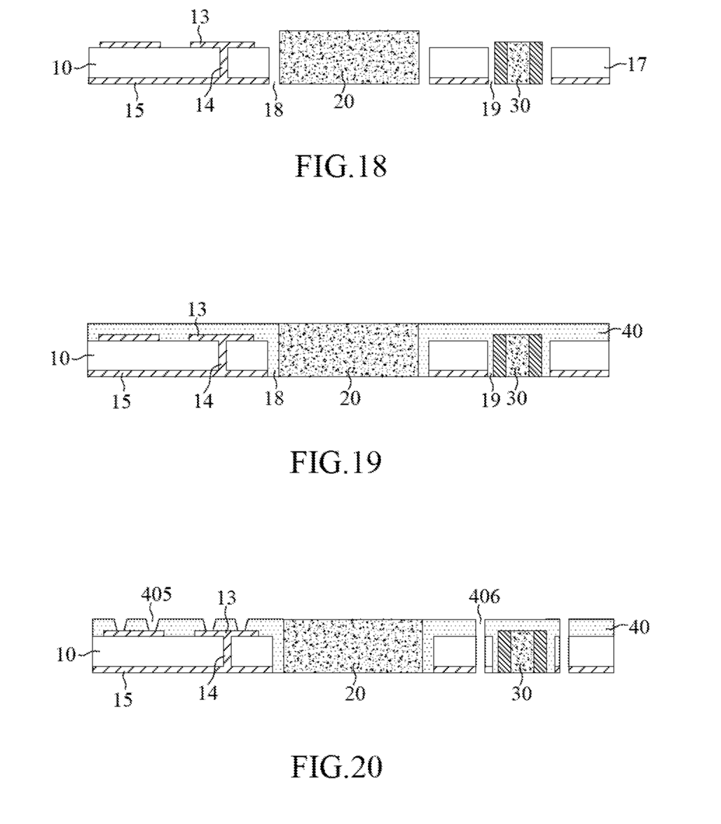

FIGS. 18-22 are schematic views showing a method of making a wiring board having a bottom wiring layer in accordance with the second embodiment of the present invention.

For purposes of brevity, any description in Embodiment 1 is incorporated herein insofar as the same is applicable, and the same description need not be repeated.

FIG. 18 is a cross-sectional view of the structure with an interposer 20 and an electronic component 30 placed in a first through opening 18 and a second through opening 19 of a base board 10, respectively. The base board 10 is similar to that illustrated in FIG. 1, except that it further includes a metallized through via 14 in the core layer 17. The metallized through via 14 extends through the core layer 17 to provide electrical connections between the top wiring layer 13 and the bottom metal film 15.

FIG. 19 is a cross-sectional view of the structure provided with a dielectric layer 40. The dielectric layer 40 is formed on the top side of the base board 10 and the top surface of the electronic component 30, and extends into gaps between the base board 10 and the interposer 20 and between the base board 10 and the electronic component 30.

FIG. 20 is a cross-sectional view of the structure provided with via openings 405 and through holes 406. The via openings 405 extend through the dielectric layer 40 to expose selected portions of the top wiring layer 13 from above. The through holes 406 extend through the base board 10 and the dielectric layer 40 in the vertical directions. The through holes 406 are formed by mechanical drilling and can be formed by other techniques such as laser drilling and plasma etching with or without wet etching.

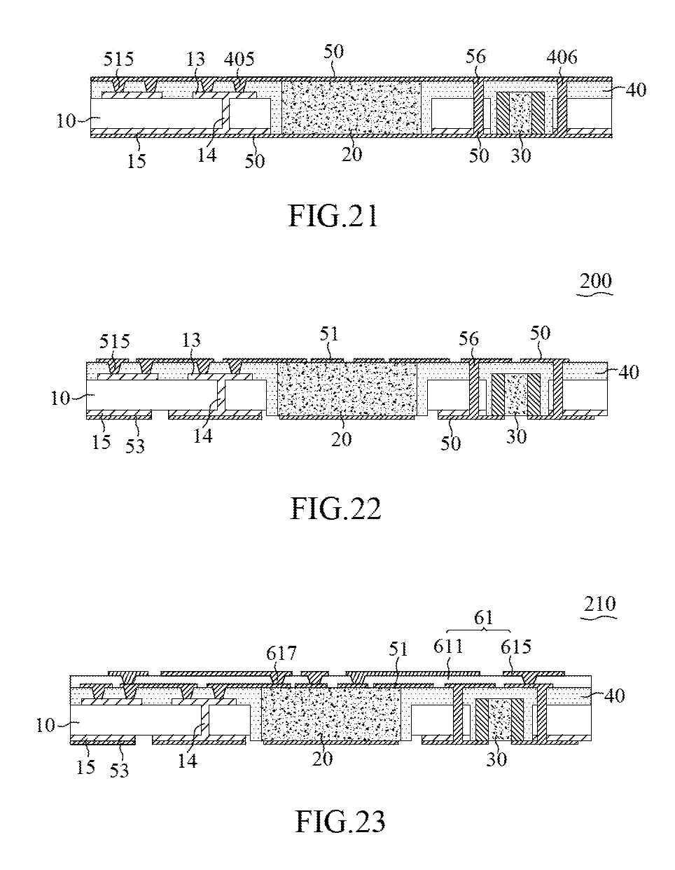

FIG. 21 is a cross-sectional view of the structure provided with a plated layer 50 on the top and bottom surfaces of the structure and into the via openings 405 and the through holes 406. The plated layer 50 fills up the via openings 405 and the through holes 406 to form metallized vias 515 and plated through holes 56, and completely covers the top and bottom surfaces of the structure.

FIG. 22 is a cross-sectional view of the structure provided with a routing circuitry 51 and a bottom wiring layer 53 by metal patterning process. At this stage, a wiring board 200 is accomplished and includes the base board 10, the interposer 20, the electronic component 30, the dielectric layer 40, the routing circuitry 51, the bottom wiring layer 53 and the plated through holes 56. The routing circuitry 51 is formed by patterning the plated layer 50 at the top surface of the structure, whereas the bottom wiring layer 53 is formed by patterning the plated layer 50 at the bottom surface of the structure as well as the bottom metal film 15. The routing circuitry 51 extends laterally on the top surfaces of the interposer 20 and the dielectric layer 40 and includes the metallized vias 515 in contact with the top wiring layer 13 of the base board 10. The bottom wiring layer 53 extends laterally on the bottom surfaces of the base board 10, the interposer 20 and the electronic component 30, and is electrically coupled to the metallized through via 14, the electronic component 30 and the plated through holes 56. As a result, the bottom wiring layer 53 can be electrically connected to the routing circuitry 51 through the top wiring layer 13, the metallized through via 14 and the plated through holes 56, and provides electrical connection between the electronic component 30 and the routing circuitry 51.

FIG. 23 is a cross-sectional view of another aspect of the wiring board according to the second embodiment of the present invention. The wiring board 210 is similar to that illustrated in FIG. 22, except that it further includes a top build-up circuitry 61 on the routing circuitry 51. In this illustration, the top build-up circuitry 61 includes a resin layer 611 and a conductive trace layer 615. The resin layer 611 covers the routing circuitry 51 from above, and the conductive trace layer 615 extends laterally on the resin layer 611 and includes metallized vias 617 in contact with the routing circuitry 51.

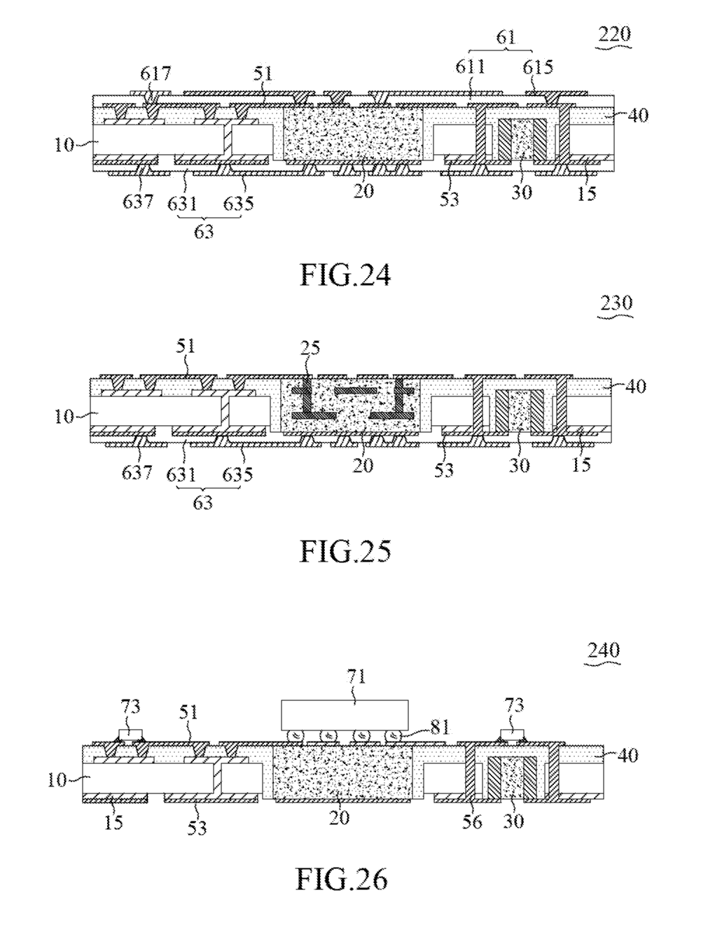

FIG. 24 is a cross-sectional view of yet another aspect of the wiring board according to the second embodiment of the present invention. The wiring board 220 is similar to that illustrated in FIG. 23, except that it further includes a bottom build-up circuitry 63 on the bottom wiring layer 53. In this illustration, the bottom build-up circuitry 63 includes a resin layer 631 and a conductive trace layer 635. The resin layer 631 covers the bottom wiring layer 53 from below, and the conductive trace layer 635 extends laterally on the resin layer 631 and includes metallized vias 637 in contact with the bottom wiring layer 53.

FIG. 25 is a cross-sectional view of yet another aspect of the wiring board according to the second embodiment of the present invention. The wiring board 230 is similar to that illustrated in FIG. 22, except that it further includes a bottom build-up circuitry 63 electrically coupled to the bottom wiring layer 53 and the interposer 20 further includes a built-in circuitry 25 electrically coupled to the routing circuitry 51. In this illustration, the bottom build-up circuitry 63 includes a resin layer 631 and a conductive trace layer 635. As a result, the built-in circuitry 25 of the interposer 20 is electrically connected to the bottom build-up circuitry 63 through the routing circuitry 51, the base board 10, the plated through holes 56 and the bottom wiring layer 53.

FIG. 26 is a cross-sectional view of a semiconductor assembly 240 with a semiconductor device 71 and passive components 73 electrically connected to the wiring board 200 illustrated in FIG. 22. The semiconductor device 71 is aligned with the interposer 20 and flip-chip mounted over and electrically coupled to the routing circuitry 51 via conductive bumps 81. The passive components 73 are mounted over the top surface of the dielectric layer 40 and electrically coupled to the routing circuitry 51.

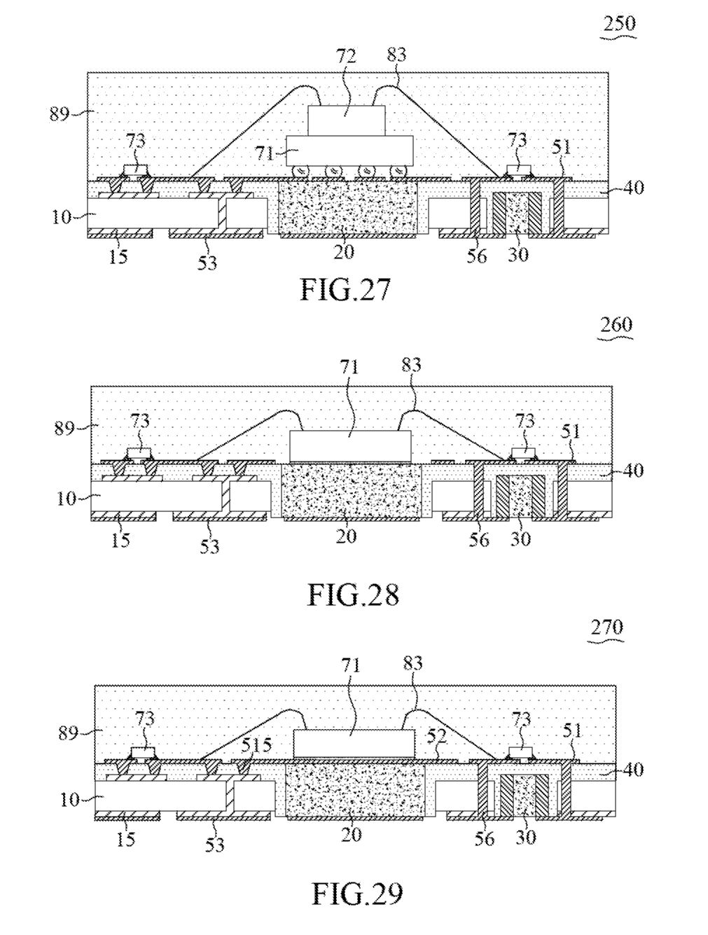

FIG. 27 is a cross-sectional view of another aspect of the semiconductor assembly according to the second embodiment of the present invention. The semiconductor assembly 250 is similar to that illustrated in FIG. 26, except that it further includes an additional semiconductor device 72 and an encapsulant 89. The additional semiconductor device 72 is mounted on the semiconductor device 71 and electrically coupled to the routing circuitry 51 through bonding wires 83. The encapsulant 89 covers the semiconductor devices 71, 72, the passive components 73 and the bonding wires 83 from above.

FIG. 28 is a cross-sectional view of yet another aspect of the semiconductor assembly according to the second embodiment of the present invention. The semiconductor assembly 260 is similar to that illustrated in FIG. 26, except that (i) the routing circuitry 51 does not laterally extend onto the interposer 20, (ii) the semiconductor device 71 is mounted over the interposer 20 and electrically coupled to the routing circuitry 51 through bonding wires 83, and (iii) an encapsulant 89 is further provided to cover the semiconductor device 71, the passive components 73 and bonding wires 83 from above.

FIG. 29 is a cross-sectional view of yet another aspect of the semiconductor assembly according to the second embodiment of the present invention. The semiconductor assembly 270 is similar to that illustrated in FIG. 28, except that the routing circuitry 51 further laterally extends onto the interposer 20 to provide a thermal pad 52 between the interposer 20 and the semiconductor device 71. In this illustration, the thermal pad 52 is electrically connected to the base board 10 through the metallized via 515 for ground connection.

### Embodiment 3

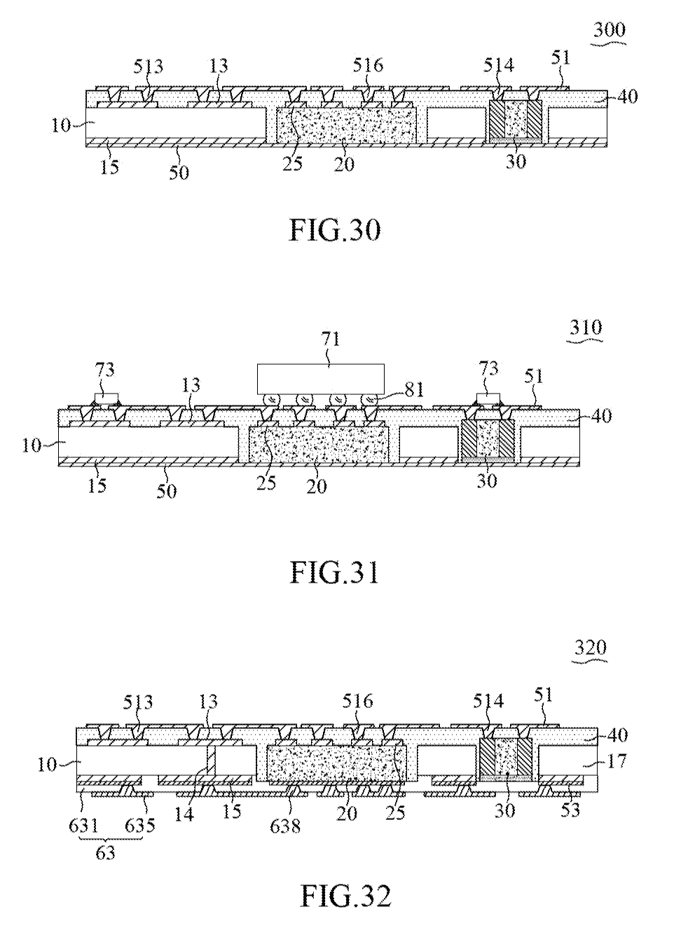

FIG. 30 is a cross-sectional view of a wiring board in which the dielectric layer further covers the top surface of the interposer in accordance with the third embodiment of the present invention.

For purposes of brevity, any description in Embodiments above is incorporated herein insofar as the same is applicable, and the same description need not be repeated.

The wiring board 300 is similar to that illustrated in FIG. 11, except that (i) the interposer 20 further includes built-in circuitry 25 at its top surface, (ii) the dielectric layer 40 further covers the interposer 20 from above, and (iii) the routing circuitry 51 further includes third metallized vias 516 connected to the top surface of the interposer 20. In this illustration, the base board 10, the interposer 20 and the electronic component 30 have the same thickness, and the first metallized vias 513, the second metallized vias 514 and the third metallized vias 516 of the routing circuitry 51 have the same depth. By the routing circuitry 51, the built-in circuitry 25 of the interposer 20 can be electrically connected to the top wiring layer 13 of the base board 10 and the electronic component 30.

FIG. 31 is a cross-sectional view of a semiconductor assembly 310 with a semiconductor device 71 and passive components 73 electrically connected to the wiring board 300 illustrated in FIG. 30. The semiconductor device 71 is aligned with the interposer 20 and flip-chip mounted over the top surface of the dielectric layer 40 and electrically coupled to the routing circuitry 51 via conductive bumps 81. The passive components 73 are mounted over the top surface of the dielectric layer 40 and electrically coupled to the routing circuitry 51.

FIG. 32 is a cross-sectional view of another aspect of the wiring board according to the third embodiment of the present invention. The wiring board 320 is similar to that illustrated in FIG. 30, except that (i) it further includes a bottom wiring layer 53 on the bottom surfaces of the base board 10 and the interposer 20 and a bottom build-up circuitry 63 electrically coupled to the bottom wiring layer 53, and (ii) the base board 10 further includes a metallized through via 14 in the core layer 17 and a bottom metal film 15 at the bottom side of the base board 10. The bottom metal film 15 is a patterned metal film that is combined with the bottom wiring layer 53 and electrically connected to the top wiring layer 13 through the metallized through via 14. In this illustration, the bottom build-up circuitry 63 includes a resin layer 631 and a conductive trace layer 635. The conductive trace layer 635 includes fourth metallized vias 638 in contact with the bottom wiring layer 53. As a result, the combination of the top wiring layer 13, the metallized through via 14 and the bottom wiring layer 53 as well as the bottom metal film 15 provides electrical connection between the routing circuitry 51 and the bottom build-up circuitry 63 so as to offer the wiring board 320 with stacking capability. Additionally, the third metallized vias 516 of the routing circuitry 51 and the fourth metallized vias 638 of the bottom build-up circuitry 63 can serve as heat pipes for thermal dissipation.

As illustrated in the aforementioned embodiments, a distinctive wiring board is configured to have an interposer, an electronic component and a base board and exhibit improved reliability. Preferably, the wiring board mainly includes an interposer, an electronic component, a base board, a dielectric layer, a routing circuitry and optionally a bottom wiring layer, wherein (i) the interposer is inserted into a first through opening of the base board and has a bottom surface substantially coplanar with the bottom side of the base board; (ii) the electrical component is inserted into a second through opening of the base board and has a bottom surface substantially coplanar with the bottom side of the base board; (iii) the dielectric layer provides mechanic bonds between the interposer and the base board and between the electronic component and the base board and has a bottom surface substantially coplanar with the bottom surface of the interposer, the bottom side of the base board and the bottom surface of the electronic component; (iii) the routing circuitry is deposited on the top surface of the dielectric layer and electrically connected with the electronic component and includes metallized vias in electrical connection with the top wiring layer of the base layer and optionally further laterally extends onto a top surface of the interposer; and (iv) the bottom wiring layer is formed at the bottom side of the base board and electrically coupled to the routing circuitry through metallized through via(s) as well as the top wiring layer of the base board or/and through plated through hole(s).

The interposer can have a thickness larger than or the same as that of the base board and is incorporated with the base board by the dielectric layer. Preferably, the interposer has high elastic modulus and low coefficient of thermal expansion (for example, 2×10⁻⁶ K⁻¹ to 10×10⁻⁶K⁻¹). For instance, the interposer can include a ceramic slug (such as Al₂O₃, AIN, silicon or the like). As a result, the interposer, having CTE matching a semiconductor device to be assembled thereon, provides a CTE-compensated platform for the semiconductor device, and thus internal stresses caused by CTE mismatch can be largely compensated or reduced. Further, the interposer also provides primary heat conduction for the semiconductor device so that the heat generated by the semiconductor device can be conducted away. Additionally, the interposer may further include a built-in circuitry at the ceramic slug and electrically coupled to the routing circuitry. Preferably, the built-in circuitry provides electrical contacts at the top surface of the interposer for next-level circuitry connection.

The electronic component may be a resistor, capacitor, inductor or any other passive or active component and is incorporated with the base board by the dielectric layer. In a preferred embodiment, the electronic component is face-up disposed in the second through opening of the base board and electrically connected to the routing circuitry through metallized vias of the routing circuitry. Optionally, the bottom surface of the face-up electronic component may be provided with a thermally conductive material. As a result, the heat generated by the electronic component can be conducted away through the thermally conductive material.

The base board can enhance routing flexibility of the wiring board. Specifically, the top wiring layer of the base board can provide additional routing in electrical connection with the routing circuitry on the dielectric layer through the metallized vias embedded in the dielectric layer. Optionally, the base board may further includes one or more metallized through vias that extend through the base board in vertical directions and provide electrically connection between the top wiring layer and the bottom wiring layer. Additionally, the base board may be used for the placement accuracy of the interposer and the electronic component. Specifically, the interior sidewalls of the first amd second through openings of the base board may serve as alignment guides for the placement of the interposer and the electronic component. The interior sidewalls of the first through opening of the base board can be laterally aligned with four lateral surfaces of the interposer to define an area with the same or similar topography as the interposer and prevent the lateral displacement of the interposer. Likewise, the interior sidewalls of the second through opening of the base board can be laterally aligned with four lateral surfaces of the electronic component to define an area with the same or similar topography as the electronic component and prevent the lateral displacement of the electronic component. As a result, the interior sidewalls of the base board in close proximity to the peripheral edges of the interposer and the electronic component can provide placement accuracy for the interposer and the electronic component.

The dielectric layer can further cover the top surface of the interposer or have a top surface substantially coplanar with the top surface of the interposer. As the dielectric layer extends into gaps between the peripheral edges of the interposer and the interior sidewalls of the first through opening and between the peripheral edges of the electronic component and the interior sidewalls of the second through opening, the interposer and the electronic component can be securely boned with the base board through the dielectric layer.

The routing circuitry on the top surface of the dielectric layer may further extend onto the top surface of the interposer. As a result, the routing circuitry can provide electrical contacts on the top surface of the interposer to allow a semiconductor device to be flip-chip attached on the interposer, or provide a thermal pad on the top surface of the interposer for a semiconductor device face-up mounted thereon. When the dielectric layer further covers the top surface of the interposer, the routing circuitry preferably further includes additional metallized vias in connection with the top surface of the interposer. For instance, the additional metallized vias in the dielectric layer may contact and be electrically coupled to the built-in circuitry of the interposer so as to provide electrical connection with the interposer. Alternatively, the additional metallized vias may serve as heat pipes in contact with the top surface of the interposer for heat dissipation. The routing circuitry can be formed by metal deposition using photolithographic process. Preferably, the routing circuitry is deposited by a sputtering process and then an electrolytic plating process.

The bottom wiring layer may further laterally extend onto the bottom surface of the electronic component or/and the bottom surface of the interposer. In a preferred embodiment, the base board includes a bottom metal film that is a patterned metal film at the bottom side of the base board and electrically connected to the top wiring layer of the base board, and the bottom wiring layer is combined with the bottom metal film. As a result, the bottom wiring layer can be electrically connected to the routing circuitry through the metallized through vias in connection with the top wiring layer and the bottom metal film. The metallized through vias extend through the base board in the vertical directions and are between the top wiring layer and the bottom wiring layer. Or/Also, the bottom wiring layer may be electrically connected to the routing circuitry through plated through holes in connection with the top wiring layer and the bottom wiring layer. The plated through holes extend through the base board and the dielectric layer in the vertical directions and are between the routing circuitry and the bottom wiring layer. Accordingly, the routing circuitry and the bottom wiring layer provide electrical contacts at the top and bottom sides of the wiring board so as to offer the wiring board with stacking capability. Additionally, when the electronic component is face-down disposed in the second through opening of the base board, the bottom wiring layer would be further electrically coupled to the electronic component. As a result, the electronic component can be electrically connected to the routing circuitry through the bottom wiring layer.

For further routing, the wiring board may further include a top build-up circuitry or/and a bottom build-up circuitry. The top build-up circuitry can be provided to cover the top surface of the interposer and the top surface of the dielectric layer as well as the routing circuitry, and be electrically coupled to the routing circuitry and preferably thermally conductible to the interposer. The bottom build-up circuitry can be provided to cover the bottom surface of the interposer, the bottom side of the base board and the bottom surface of the electronic component as well as the bottom wiring layer, and be electrically connected to the bottom wiring layer and preferably thermally conductible to the interposer. In a preferred embodiment, the top build-up circuitry and the bottom build-up circuitry are multi-layered build-up circuitries without a core layer, and each includes at least one resin layer and at least one conductive trace layer that fills up via openings in the resin layer and extends laterally on the resin layer. The resin layer and the conductive trace layer are serially formed in an alternate fashion and can be in repetition when needed. The outmost conductive trace layers of the top and bottom build-up circuitries can respectively accommodate conductive joints, such as solder balls or bonding wires, for electrical communication and mechanical attachment with an assembly, an electronic device or others.

The present invention also provides a semiconductor assembly in which a semiconductor device such as chip is mounted over the top surface of the interposer of the aforementioned wiring board and electrically coupled to the routing circuitry. Specifically, the semiconductor device can be electrically connected to the wiring board using various using a wide variety of connection media including conductive bumps (such as gold or solder bumps) on the routing circuitry of the wiring board or bonding wires attached to the routing circuitry of the wiring board.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction. For instance, in a preferred embodiment, the bottom build-up circuitry covers the interposer, the base board and the electronic component in the downward direction regardless of whether another element such as the bottom wiring layer is between the bottom build-up circuitry and the interposer, between the bottom build-up circuitry and the base board, and between the bottom build-up circuitry and the electronic component.

The phrases “mounted on” and “attached on” include contact and non-contact with a single or multiple support element(s). For instance, the semiconductor device can be attached on the interposer regardless of whether the semiconductor device is separated from the interposer by a the routing circuitry and the conductive bumps.

The phrase “aligned with” refers to relative position between elements regardless of whether elements are spaced from or adjacent to one another or one element is inserted into and extends into the other element. For instance, in a preferred embodiment, the interior sidewalls of the base board are laterally aligned with the peripheral edges of the interposer/electronic component since an imaginary horizontal line intersects the interior sidewalls of the base board and the peripheral edges of the interposer/electronic component, regardless of whether another element is between the interior sidewalls of the base board and the peripheral edges of the interposer/electronic component and is intersected by the line, and regardless of whether another imaginary horizontal line intersects the peripheral edges of the interposer/electronic component but not the interior sidewalls of the base board or intersects the interior sidewalls of the base board but not the peripheral edges of the interposer/electronic component. Likewise, in a preferred embodiment, some metallized vias of the routing circuitry are aligned with the interposer.

The phrase “in close proximity to” refers to a gap between elements not being wider than the maximum acceptable limit As known in the art, when the gap between the peripheral edges of the interposer/electronic component and the interior sidewalls of the base board is not narrow enough, the interposer/electronic component may not be accurately confined at a predetermined location. The maximum acceptable limit for a gap between the peripheral edges of the interposer/electronic component and the interior sidewalls of the base board can be determined depending on how accurately it is desired to dispose the interposer/electronic component at the predetermined location. Thereby, the descriptions “the peripheral edges of the interposer in close proximity to the interior sidewalls of the first through opening” and “ the peripheral edges of the electronic component in close proximity to the interior sidewalls of the second through opening” mean that the gap between the peripheral edges of the interposer/electronic component and the interior sidewalls of the through opening is narrow enough to prevent the location error of the interposer/electronic component from exceeding the maximum acceptable error limit For instance, the gaps in between the peripheral edges of the interposer and the interior sidewalls of the first through opening and between the peripheral edges of the electronic component and the interior sidewalls of the second through opening may be in a range of about 25 to 100 microns.

The phrases “electrical connection”, “electrically connected” and “electrically coupled” refer to direct and indirect electrical connection. For instance, in a preferred embodiment, the electronic component can be electrically connected to the built-in circuitry of the interposer through the routing circuitry but does not contact the built-in circuitry of the interposer.

The wiring board according to the present invention has numerous advantages. The interposer provides CTE-compensated platform for the attachment of a semiconductor device and also establish a heat dissipation pathway for spreading out the heat generated by the semiconductor device. The electronic component enhances the electrical characteristics of the semiconductor assembly. The base board provides mechanical support and enhances the routing flexibility for the wiring board. The dielectric layer provides mechanical bonds between the interposer and the base board and between the electronic component and the base board. The routing circuitry provides horizontal electrical routing and vertical electrical routing to electrically connect another horizontal electrical routing provided in the base board and the electronic component. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a wiring board having an interposer and an electronic component incorporated therein, the method comprising steps of:
providing a base board having a top side, a bottom side, a first through opening, a second through opening and a top wiring layer at the top side thereof, wherein each of the first through opening and the second through opening has interior sidewalls extending from the top side and the bottom side;
inserting an interposer into the first through opening of the base board, and inserting an electronic component into the second through opening of the base board, wherein the interposer includes a ceramic slug;
forming a dielectric layer on a top surface of the electronic component and the top side of the base board and into gaps between peripheral edges of the interposer and the interior sidewalls of the first through opening and between peripheral edges of the electronic component and the interior sidewalls of the second through opening; and
forming a routing circuitry on a top surface of the dielectric layer and electrically connected to the electronic component and to the base board through metallized vias.

2. The method of claim 1, wherein the interposer is thicker than the base board and has a top surface substantially coplanar with the top surface of the dielectric layer, and the routing circuitry further laterally extends onto the top surface of the interposer.

3. The method of claim 1, further comprising a step of forming a bottom wiring layer at the bottom side of the base board, wherein the bottom wiring layer is electrically coupled to the routing circuitry.

4. The method of claim 3, wherein the bottom wiring layer further laterally extends onto the bottom surface of the electronic component, and the electronic component is electrically connected to the routing circuitry through the bottom wiring layer.

5. The method of claim 3, wherein the bottom wiring layer further laterally extends onto the bottom surface of the interposer.

6. The method of claim 1, wherein the interposer further includes a built-in circuitry, and the routing circuitry is further electrically connected to the built-in circuitry of the interposer.

7. The method of claim 6 further comprising a step of forming a top build-up circuitry that covers the routing circuitry and the interposer, wherein the top build-up circuitry includes at least one resin layer and at least one conductive trace layer in an alternate fashion, and the conductive trace layer is electrically coupled to the built-in circuitry of the interposer and the routing circuitry.

8. The method of claim 3, further comprising a step of forming a bottom build-up circuitry that covers the bottom wiring layer, the interposer and the electronic component, wherein the bottom build-up circuitry includes at least one resin layer and at least one conductive trace layer in an alternate fashion, and the conductive trace layer is electrically coupled to the bottom wiring layer.
